(19) United States
(12) Patent Application Publication
(10) Pub. No.: US 2021/0269314 A1
(43) Pub. Date: Sep. 2, 2021

(54) A DIAMOND HAVING NANOSTRUCTURES ON ONE OF ITS SURFACE TO GENERATE STRUCTURAL COLORS AND A METHOD OF PRODUCING THEREOF

(71) Applicants: IIA Technologies Pte Ltd., Singapore (SG); AGENCY FOR SCIENCE, TECHNOLOGY AND RESEARCH (A*STAR), Singapore (SG)

(72) Inventors: Kambiz ANSARI MAHABADI, Singapore (SG); Zhaogang DONG, Singapore (SG)

(21) Appl. No.: 17/255,431

(22) PCT Filed: Jun. 17, 2019
(86) PCT No.: PCT/SG2019/050300

§ 371 Date: Dec. 23, 2020

(30) Foreign Application Priority Data
Jun. 25, 2018 (SG) 10201805438T

(51) Int. Cl. C01B 32/28; C30B 29/04; C30B 33/12

(52) U.S. Cl. CPC C01B 32/28; B82Y 20/00; C30B 33/12; C30B 29/04

(57) ABSTRACT

A diamond comprising of: at least one surface; and a plurality of nanostructures formed on the at least one surface of the diamond, wherein the plurality of nanostructures generates one or more structural colours on the surface of the diamond.

### FIELD OF INVENTION

The present invention relates to a diamond having nanostructures on one of its surface to generate structural colours and a method of producing thereof. This invention can be applicable in, for example, gems, jewelries, photonics, optics and other industrial areas.

### BACKGROUND

Structural colours can be created when light interacts with metallic nanostructures to selectively reflect or transmit wavelengths of light at resonance of oscillations of free electrons resulting into a plasmonic phenomenon. By capitalizing on this phenomenon, a high resolution image, for example 100,000 dots per inch (dpi), which is beyond the optical diffraction limit of light, has been achieved.

However, the plasmonic resonance phenomenon may only occur on conductive films (e.g., Au or Ag metal films) that are deposited on dielectric nanostructures. The deposition of metal films require complex fabrication steps which are often costly. Furthermore, the deposited metal films may not last long rending the application to be short-lived. Notwithstanding the above, colours generated by way of the plasmonic resonance phenomenon on the conductive films may have limited colours (i.e., a small subset in CIE colour gamut) and non-optimal colours saturation.

### SUMMARY OF INVENTION

In one embodiment, a diamond includes at least one surface and a plurality of nanostructures. The plurality of nanostructures are formed on the surface of the diamond. The plurality of nanostructures generates one or more structural colours on the surface of the diamond.

In another embodiment, a method of forming a diamond that displays a structural colours is provided. The method includes a step to provide a surface of the diamond. The method further includes a step to form a plurality of nanostructures on the surface of the diamond. The plurality of nanostructures generate a structural colours when shined with a visible light.

### BRIEF DESCRIPTION OF THE DRAWINGS

Further features of the disclosed techniques, their nature and various advantages, will be apparent upon consideration of the following detailed description, taken in conjunction with the accompanying drawings, in which like reference characters refer to like parts throughout, and in which:

FIGS. 1A and 1B show a cross-sectional view and a perspective view, respectively, of an exemplary diamond having multiple nanostructures formed on a surface of the diamond, to which the multiple nanostructures generates structural colours on the surface of the diamond in accordance with one embodiment.

FIGS. 2A and 2B shows exemplary color effects generated from reflection mode and transmission mode, respectively, when diameter (D) and gap (g) are varied in accordance with one embodiment.

FIG. 3 shows spectral analysis of two red identified boxes in FIG. 2A in accordance with one embodiment.

FIG. 4 shows an exemplary gemstone product in accordance with one embodiment.

FIG. 5 shows a flow chart on an exemplary method of forming a diamond that generates structural colours in accordance with one embodiment.

### DETAILED DESCRIPTION

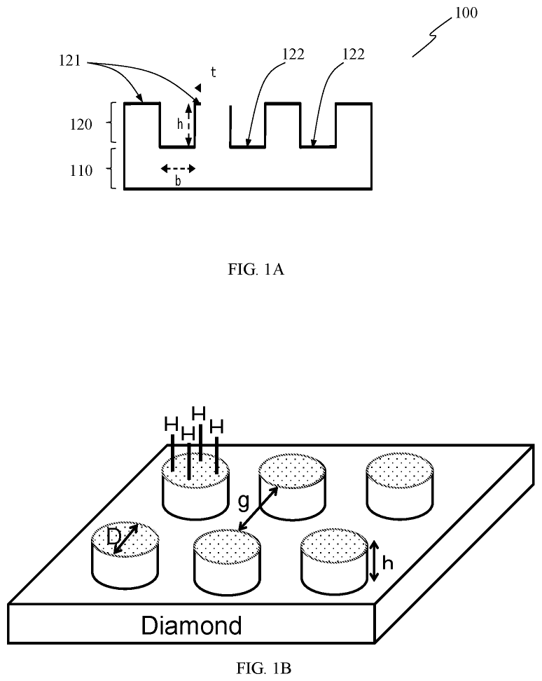

FIGS. 1A and 1B show cross-sectional and perspective views, respectively, of an exemplary diamond having multiple nanostructures formed on its surface, to which these multiple nanostructures generates a structural colour in accordance with one embodiment. As shown in the FIG. 1A, diamond 100 include surface 122 and multiple nanostructures 121, which extends vertically from bulk 110.

In one embodiment, diamond 100 can be: any diamond type (e.g., Type IIa, Type Ia, etc.), any origin (e.g., mined, high-pressure high-temperature (HPHT), and chemical vapor deposition (CVD)), and suitable for any application, such as, electronic applications, optical applications, mechanical applications, etc.

In addition, diamond 100 can also have impurities and/or defects. A diamond with these impurities and/or defects may display an intrinsic colour. In one exemplary embodiment, a lab grown diamond with nitrogen impurities may have a brown intrinsic colour. Specifically, a diamond having nitrogen concentrations between 5 parts per billion (ppb) to tens of parts per million (ppm) may display a brownish intrinsic colour that spans from a light brown colour to a dense brown colour.

It should be appreciated that diamond 100 in FIG. 1A may be an entire piece of a diamond or a merely a portion of a big diamond (e.g., a surface of diamond). Diamond 100, if is an entire diamond, may also be referred to as a diamond plate. Alternatively, diamond 100 being merely a portion of a big diamond, then the big diamond may either be a large diamond plate or a large gemstone.

As shown in FIG. 1A, surface 122 is a top surface of bulk 110. Surface 122 conditions and/or characteristics is an important in generating the structural colours. In one exemplary embodiment, surface 122 may have a particular crystallographic orientation (e.g., crystallographic orientation [100], [110] or [111]). It should be appreciated that different crystallographic orientation may affect a final structural colour that would eventually be generated by nanostructures 121.

In another exemplary embodiment, surface 122 where nanostructures 121 are formed is a hydrogen terminated (H-terminated) surface. The H-terminated surface include a thin layer of hydrogen termination (H-termination), which behaves similarly as a metal layer despite there being no deposition of metal layer. The H-terminated surface, together with multiple nanostructures 121, may generate a plasmonic effect, which would thereby generate structural colours, in one embodiment.

It should be appreciated that H-terminated diamond surfaces behaves similarly as a metal layer because of its high electric dipole moment which attracts negative polar ions, such as surface adsorbates (water molecules), and this leads to the creation of a hole accumulation layer at the surface. Furthermore, the H-terminated diamond surface possesses a strong surface conductivity which is attributed to its negative electron affinity (EA-) plus a strong hydrophobicity (and thus a strong lipophilicity) with a water contact angle between 71° and 79°.

Alternatively, surface 122 may be an oxygen terminated (O-terminated) surface. The O-terminated surface include a thin layer of oxygen termination (O-termination). In contrast to the H-terminated diamond surface, an O-terminated diamond surface possesses a positive electron affinity which indicates its strong hydrophilicity. The O-terminated surface of a diamond may have a higher electro-negativity than a carbon, which is attributed by a positive electron affinity (EA+).

In another alternative embodiment, a surface of a diamond may have both H-termination and O-termination (not shown). For example, the surface may have an area that is dedicated as H-terminated while another area is dedicated as an O-terminated. An embodiment that includes H-termination and O-termination may enable an on/off switching of generating structural colour despite having identical nanostructures. The combination of H-terminated and O-terminated on a surface may also assist in controlling light interferences (i.e., constructive or destructive interferences).

In another alternative embodiment, a surface of a diamond may be a non-planar surface (not shown). A non-planar surface surfaces may also be referred to as (i.e., three-dimensional (3D) surfaces).

Still referring to FIG. 1A, nanostructures 121 extends vertically from surface 122. In one embodiment, nanostructures 121 are composed from the same material as with bulk 110. In another embodiment, the nanostructures 121 may be formed using a self-assembly process to form either positive or negative nanostructures onto to surface 122.

It should be appreciated that nanostructures 121 can also be referred to as “nanoposts”. The term “nanopost” basically refers to nanostructure 121 extending upwards from surface 122. In one embodiment, nanostructures 121 may have a particular cross-sectional shape. For example, the cross-sectional shapes may be nanodisks or more specifically square, circle, triangle, ellipse, hexagon, octagon, polygon and other trigonometric cross-sectional shapes. In another embodiment, nanostructures may be grouped by way of different cross-sectional shapes (not shown). For example, one of the groups of nanostructures may have a first cross-sectional shape and another group of nanostructures may have a second cross-sectional shape that is different than the first cross-sectional shape. The term “cross-sectional shape” means a shape of a transverse plane that is cutting through the nanostructure perpendicular to a vertical symmetry axis of the nanostructure 121.

Furthermore, nanostructures 121 may also have a particular shape when viewed from top. FIG. 1B illustrates circular shaped nanostructures 121 when viewed from the top, which are formed when the nanostructures 121 are in cylindrical form. Other shapes that the nanostructures when viewed from the top may take includes a rectangle, a square, hexagon, octagon, polygon and other trigonometric shapes, in one embodiment. In another embodiment, nanostructures may be grouped by way of different shapes when viewed from top (not shown). For example, one of the groups of nanostructures may have a first shape when viewed from the top and another group of nanostructures may have a second shape when viewed from the top, which is different than the first shape.

As shown in the embodiment of FIG. 1A, each nanostructure 121 can be defined by its dimensional parameters such as length of top surface (t), height (h) and distances between two adjacent nanostructures (b). With respect to FIG. 1B, when nanostructures 121 are cylindrical, the length of the top surface can also be represented by D (for diameter) and distances between two adjacent nanostructures represented by g (for gap).

In one embodiment, the length of top surface (t) or (D) may range between 100 nanometer (nm) to 500 nm, the height (h) of less than 500 nm and the distance between two adjacent nanostructures (b) or (g) may range between 40 nm to 200 nm. It should be appreciated that the dimensional parameter are dependable upon techniques and processes in which the nanostructures are fabricated, and therefore should not be considered as limited.

It should be appreciated that smoothness of top surface, bottoms surface and sidewall surface are critical to generate a particular structural colour. In one embodiment, the smoothness of the top surfaces of the nanostructures, the bottom/floor surfaces between the nanostructures, the bottom surface of cavity type nanostructures and the sidewall surfaces of the nanostructures may be less than 20 nm. Depending upon the capability to achieve the smoothness, the surface smoothness of the top surfaces of the nanostructures, the bottom/floor surfaces between the nanostructures, the bottom surface of cavity type nanostructures and the sidewall surfaces of the nanostructures may be less than 1 nm.

Another factor that is important to generate a particular structural colour is the sidewall angle (or can also referred to as verticality of the nanostructures). In one embodiment, the sidewall angle of the nanostructures may be less than 5°. In a preferred embodiment, and depending upon the technique and processes that are employed to create nanostructures, the sidewall angle of the nanostructures maybe less than 1°.

Another factor that is important to generate a particular structural colour is: (i) straight lines, (ii) sharpness of the edges and (iii) curvature of the corners that define the structural precision of the nanostructures. In one embodiment, the line edge roughness (LER) defining arrays of parodic parallel lines/spaces of nanostructures is less than 5 nm.

It should be appreciated that a CVD diamond growth technology is able to control and engineer the material refraction index by controlling the density and distribution of: (i) impurities incorporated during CVD growth into crystal lattice, (ii) vacancies, (iii) dislocations, and/or (iv) defects. The capability to engineer properties of a diamond at molecular levels combined with fabrication of nanostructures may enable unique optical characteristics such as diffraction of light that was not previously observed.

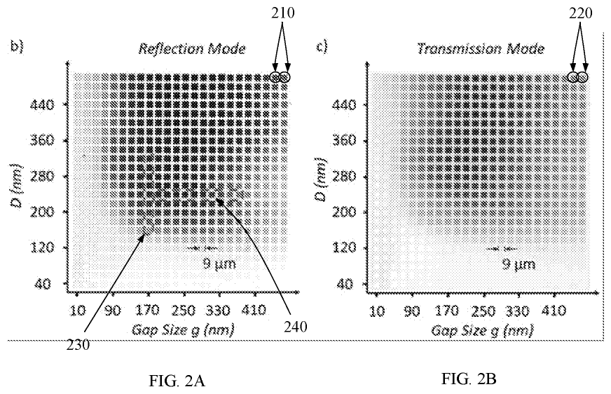

FIGS. 2A-2B, meant to be illustrative and not limiting, illustrates impact of varying dimensional parameters towards structural colours in accordance with one embodiment of the present invention. Both FIGS. 2A-2B are represented by multiple boxes 210 and 220 that are displaying different structural colours. Each box 210 and 220 is encompassing an area of 9 microns (μm)×9 μm, and includes multiple nanostructures within that area. In one embodiment, the nanostructures formed within boxes 210 and 220 may be similar to nanostructure 121 of FIG. 1A. The nanostructures formed within each box may be arranged in a periodic manner and/or in an array formation.

Each box 210 and 220 include multiple nanostructures. These nanostructures may also be referred to as “nanopost”. However, each box is different from another box in terms of: (i) edge-to-edge distances (represented by “g”) between two adjacent nanostructures (i.e., neighboring nanostructures), (ii) diameter sizes (represented by “D”) of the nanostructure. It should be appreciated the centre-to-centre distance between the adjacent periodic nanostructures is called “pitch”, and can be defined as (D+g) where D is for circular shape defining the cross sectional dimension of the nanostructures. In reference to FIGS. 2A and 2B, top right corners are having a largest pitch value and a largest diameter value whereas bottom left corners are having a smallest pitch value and a smallest diameter values.

In one embodiment, variations in structural colours are generated because of the diffraction of light from both high-refraction-index resonances of magnetic and electric fields by diamond as dielectric material combined with arrays of periodic nanostructures that behaves like scattering gratings. The light diffraction due to combination of material and periodic nanostructures yields to filtration of specific wavelength(s), thereby generating a structural colour. The scattering may also be referred to as “Mei scattering”. The sizes (D or L) and gaps (g) in arrays of nanostructures forms two dimensional (2D) gratings where the light fields follow the periodicity in material permittivity and permeability so light interference leads to resonances at wavelengths of visible range and the colours in the pixels are formed. When the nanostructures scatter selects a wavelength of a visible light (in reflection mode or transmission mode) with resonance that confines the light with minimal loss and enough intensity, the corresponding colour can be detected in optical bright-field microscope. Thereby, a person skilled in the art would be able to vary the structural colours by controlling the sizes of the nanostructures and the gaps between the nanostructures. Further, and through the extension of knowing the manner to generate the structural colours, one can form an image.

FIG. 2A shows the structural colors generated as a result of reflection mode when diameter (D) and gap (g) are varied. At one extreme end, which is top right corner, box 210 provides blue structural colours (i.e., dark structural colours) when the diameter of the nanostructure is 500 nm and the gaps between two consecutive nanostructures within the box 210 is 500 nm. At the other extreme end, which is bottom left corner, box 210 provides a colorless effect when the diameter of nanostructure is 10 nm and the gaps between two consecutive nanostructures within the box 210 is 10 nm. However, boxes 210 at the bottom right corner and top left corner are showing identical structural colours. This clearly indicates that boxes 210 with similar periodicity of nanostructures would show similar colours. FIG. 2A also shows a large gamut of structural colours in the reflection mode that are generated by varying the diameter and gaps of the nanostructures.

FIG. 2B, on the other hand, shows structural color generated as a result of transmission mode when diameter and gap are varied. At one extreme end, which is bottom left corner, box 220 is giving a greyish structural colours when the diameter of nanostructure is 500 nm and the gaps between two consecutive nanostructures within the box 210 is 500 nm. At the other extreme end, which is top right corner, box 220 is giving a colorless effect when the diameter of nanostructure is 10 nm and the gaps between two consecutive nanostructures within the box 220 is 10 nm. Similar to FIG. 2A, boxes 220 at the bottom right corner and top left corner are showing identical structural colours. Furthermore, FIG. 2B also shows a large gamut of structural colours in transmission mode that are being generated by varying the diameter and gaps of the nanostructures.

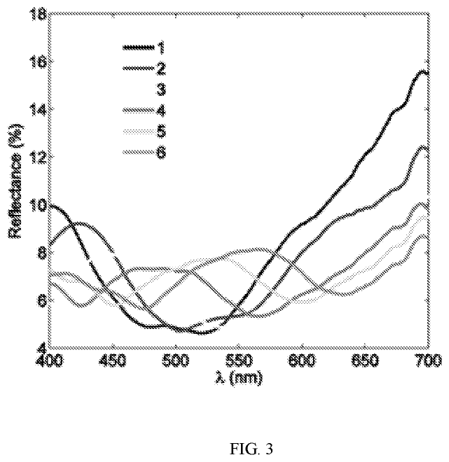

It should be appreciated that the structural colours of each box 210 or 220 of FIGS. 2A and 2B, respectively, may also vary depending on the wavelength of light to which is transmitted upon. This can be observed by spectral analysis of boxes 210 within the two red dotted boxes 230 and 240 as shown in FIG. 3.

FIG. 3, meant to be illustrative and not limiting, illustrates spectral analysis of boxes 210 within the two red dotted boxes 230 and 240 of FIG. 2A. The multiple coloured lines represented by 1-6 is indicative of box 210 in FIG. 2A. For example, the line 1 is indicative of box 210 located at the bottom side of box 230 and left side of box 240. In contrast, line 2 is indicative of box 210 located at the upper side of box 230 and right side of box 240.

Each line 1-6 in the spectra exhibits peaks and dips. The dip in the spectra indicates high proportion of absorption whereas the peak indicates high proportion of reflection. For example the dip for line 1 indicates that a smaller diameter nanostructures are due to power absorption by the disks and, to a lesser extent, the back reflector. Together, they act as an antireflection layer at this wavelength. In contrary, the dips for large diameter nanostructure such as line 4 are resultant from the interference between wide nanostructures. At this condition, optical power flows around the nanostructures, through the gaps. The peaks correspond increased in scattering strength. It is intensified for larger diameter nanostructures because of their increased scattering strengths. In horizontal where the diameter remains constant and the gap size is varying, the colour changes gradually from red to green.

In one embodiment, nanostructures having asymmetric geometry may also have impact on the structural colours. For example, in the rectangular shaped nanostructures, whereby the edges are defined by Lx (length in X direction) and Ly (length in Y direction), the structural colours begin to vary with polarization angle. For example, when Lx=50 nm and Ly=60 nm, the colour changes from light red at 0° to yellow at 90°. However, when Lx=180 nm and Ly=60 nm, the colour changes from dark red at 0° to light red at 90°.

Furthermore, intrinsic colours generated by bulk of the diamond (as described in FIG. 1A) can be combined with the nanostructures to further contribute different variations of colour and further enhance the colour gamut that can be achievable simply by addition of nanostructures or simply by having impurities. For example, an initial brown coloured diamond will affect the reflected or transmitted colours that are generated by nanostructures in such a way that the ultimate colour would be a combination of both. A comparison between colours generated by nanostructures on colourless diamond with colours generated by nanostructures on diamond with say brown colour shows that the colour coordinates of hue and saturation and brightness would be different.

In another embodiment, if the diamond with nanostructures is annealed (heat treatment) and/or irradiated with high energetic particles or radiation (electron, proton, neutron, gamma etc), they are well known to change the intrinsic colour of the diamond. This is because of influence on internal defects and/or impurities. These processes allow the impurities and vacancies to migrate and/or change the crystal lattice defects (interstitials and vacancies) therefore the colour of the bulk of diamond would be changed. This will modify the generated colours coming as a combination from nanostructures on the surface with colours from bulk of treated diamonds leading to an even broader colour gamut.

In another embodiment, the nanostructures may be formed non-planar surfaces. In other words, the nanostructures may be formed on multiple levels of platforms with different heights at macro/microscales. As a result of these non-planar surfaces, the generated colour would different despite the nanostructures have identical size and gaps. The nanostructured formed on the non-planar surfaces may help to create a 3D diffraction pattern effect or holographic patterns. Another add-on factor to control generation of colour lead to increase in colour gamut that is formed by 3D patterns of the nanostructures on diamond.

Therefore, in one exemplary embodiment, a person skilled in the art is capable of forming structural colours palate by using the disclosed structural colours variations in FIGS. 2A, 2B and 3 and/or by using asymmetric geometry, bulk colour, and annealing. The structural colours palate may be made up of multiple pixels, where each pixel may be defined either by a single nanostructure or a group of nanostructures for displaying red, green and blue colours (RGB). Using this pixel, a high resolution colour image 105 dots per inch (d.p.i) or more can be achieved. This resolution may be varied by controlling the size of each pixel. For example, the resolution can be increased by reducing sizes of each pixel. Within each pixel area, the nanostructures may be positioned in regular arrays or uniform distribution, or may be positioned randomly but maintaining the spacing, g, between adjacent nanostructures.

Furthermore, the colour image may be observable using a bright-field illumination. The bright-field colour images with resolutions up to the optical diffraction limit may be obtained. Colour information may be encoded in the dimensional parameters and positions of nanostructures, so that tuning of the nanostructures may determine the colours of the individual pixels. The colour imaging of the various images may be applied to create a full-colour image or micro-image with high resolution, sharp colour changes and fine tonal variations.

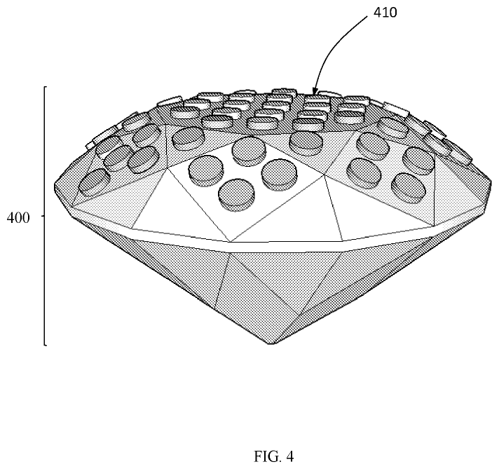

FIG. 4, meant to be illustrative and not limiting, shows one application of the invention on a gemstone in accordance with one embodiment of the present invention. Gemstone 400 includes multiple surfaces having multiple nanostructures 410. The purpose these multiple nanostructures 410 are formed on the surfaces to generate structural colours when the surfaces is shined with light. The nanostructures act as diffraction gratings for the colors to be generated. As discussed above, the light diffraction within the nanostructures leads to resonances at specific wavelengths proportional to structural dimensions and designs. This occurs both in reflection and transmission modes. The diamond will enhance the color selectivity and widens the color gamut, the angle view independency and the color saturation. In one embodiment, nanostructures 410 may be similar to nanostructures 121 of FIG. 1A.

As shown in the embodiment of FIG. 4, gemstone 400 is in a form of round brilliant cut. However, it should be appreciated that a gem diamond can be of various other diamond cuts. For example, the gem diamond can be in a form princess cut, cushion cut, emerald cut, etc, in alternative embodiments. A person skilled in the art appreciates that the cut greatly affects a diamond's brilliance.

The diamond cut constitutes symmetrical arrangement of facets, which together modify the shape and appearance of a gem diamond. For example, gemstone 400 is having 58-facets (number of facets for round brilliant cut). Each facet of a gem diamond is generally a planar surface. In one embodiment, each surface may be similar to surface 110 of FIG. 1A.

Referring still to the embodiment of FIG. 4, the nanostructures are only formed on the facets that are located at top-half of gemstone 400. The structural colours, generated due to these nanostructures, encompass the entire top surfaces of the gem diamond. However, it should be appreciated that the nanostructures can also be formed on the facets that are located at the bottom-half of the gem diamond or selected surfaces of gem diamond.

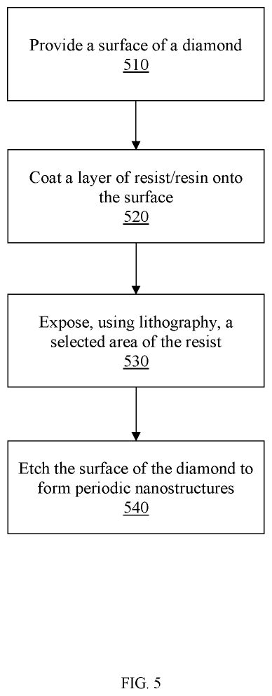

FIG. 5, meant to be illustrative and not limiting, illustrates a flow chart on a method of forming a diamond that displays structural colours. In one embodiment, the formed diamond from the method in FIG. 5 may be similar to diamond 100 of FIG. 1A or a gemstone such gemstone 400 of FIG. 4.

At step 510, a surface of diamond is provided. In one embodiment, the surface may be similar to surface 110 of FIG. 1A. Before the surface is provided, it is essential that the surface is prepared. As stated under FIG. 1A, the surface is an H-terminated surface. With respect to diamond having CVD origin, H-terminated surface can be obtained as a result of its growth. Specifically, hydrogen being a main gas component within the mixture of CVD growth, (i.e., more than 90% is H2) leads to a hydrogenated diamond surface termination.

In one embodiment, the conductivity of the surface can be increased by exposing the surface to acidic vapors. In addition, hydrogen peroxide, an intermediate in the electrochemical reduction of oxygen, may also increase the hydrogenation.

The surface of diamond has included smoothness of less than 1 nm and has to be flat over the entire area. It should be appreciated that the diffraction of light within nanostructures is dependent, amongst others, on the surface smoothness and flatness.

At step 520, a resist is coated onto the surface of the diamond. A person skilled in the art appreciates the type of resist that may be coated onto the surface of the diamond. The resist is coated so that exposure, as mentioned in step 530, can be performed onto the surface. In one embodiment, the resist may be a hardmask such as HSQ, Ni—Ti, and Al. The hardmask is utilized to fabricate diamond nanostructures with high aspect ratios.

At step 530, a selected area on the diamond surface is exposed by way of photolithography. In one embodiment, the selected area is similar to the area in which the nanostructures are to be formed. Alternatively, the selected area may be similar to the area in which etching, as per step 540, may be performed.

In an alternative embodiment, the selected are on the diamond surface is exposed by way of electron beam (e-beam) lithography. The e-beam lithography is the practice of scanning a focused beam of electrons to draw custom shapes on a surface covered with an electron-sensitive film called a resist (exposing). The electron beam changes the solubility of the resist, enabling selective removal of either the exposed or non-exposed regions of the resist by immersing it in a solvent (developing).

At step 540, the surface of the diamond is etched to form multiple nanostructures. The etching process may transfer pattern onto the surface of the diamond. In one embodiment, the final product after step 540 may be similar to embodiment shown in FIG. 1A.

The pattern transfer into diamond may be carried out utilizing dry etching techniques, in one embodiment. Alternatively the pattern transfer into the diamond may be carried out utilizing inductive coupling plasma reactive ion etching (ICP/RIE).

It should be appreciated that typical RIE processes include formation of plasma, which the ions are accelerated towards the substrate, and therefore may physically remove the material. The process may have a low selectivity between resist/resin materials patterned on diamond and therefore is not always ideal for high resolution high density and high aspect ratio nano-patterning of diamond surface. In one exemplary embodiment, an oxygen-carbon fluoride (O2-CF4) gas mixture at a pressure of 10-100 mTorr to prepare mechanically processed single crystal diamond surfaces for CVD growth is suitable.

ICP etching process, on the other hand, is a chemical etching process in which a plasma is used to breakdown etching gases into free radicals (i.e. neutral species) and ions (i.e. charged species). There is a gap between the plasma that forms in remote distance from the substrate being etched. In the gap between the plasma and the diamond being etched, the vast majority of the ions generated in the plasma are removed. Thus, majority of species that reach the diamond are neutral. Since atoms in a higher energy state in the substrate, such as those in a region with extended lattice imperfections (e.g. a damaged region), are easier to etch, then this type of etch generally preferentially etches the regions of extended lattice imperfections, roughening the surface.

The dry etching technique is preferable for a tungsten hardmask. As mentioned under step 520, the hardmask together with dry etching technique may enable formation of high aspect ratio nanostructure.

In one embodiment, the ICP plasma gas mixture used in the plasma etching consists of inert gas and chlorine and said inert gas is argon, helium, neon, krypton, xenon, or a mixture of more than one of these, and wherein the following conditions is satisfied: (a) the roughness Rq of the plasma etched surface is less than the roughness of original surface, and Rq of the plasma etched surface is less than 1 nm. (b) the original diamond surface has been mechanically processed prior to plasma etching and wherein the plasma-etched surface is substantially free from residual damage due to mechanical polishing processes.

The etching parameters have to be varied to obtain verticality, straight lines and sharp/curved corners for the nanostructures. The etching process requires optimization of etching parameters include the power (in Watts), the pressure, the type of gas and the duration of etching which are dependent on type of nonpatterns as well.

Although the method operations were described in a specific order, it should be understood that other operations may be performed in between described operations, described operations may be adjusted so that they occur at slightly different times or described operations may be distributed in a system which allows the occurrence of the processing operations at various intervals associated with the processing, as long as the processing of the overlay operations are performed in a desired way.

The foregoing is merely illustrative of the principles of this invention and various modifications can be made by those skilled in the art without departing from the scope and spirit of the invention.

In one embodiment, a diamond, comprising: at least one surface; and a plurality of nanostructures formed on the at least one surface of the diamond, wherein the plurality of nanostructures generates one or more structural colours on the surface of the diamond.

The diamond as defined in the above embodiment, generate a visual perception selected from a group of perceptions consisting of: perception of image, perception of depth and perception of size.

The diamond as defined in the above embodiment, wherein nanostructures within the plurality of nanostructures are identical in shapes.

The diamond as defined in the above embodiment, wherein nanostructures within the plurality of nanostructures are categorized to at least two different shapes.

The diamond as defined in the above embodiment, wherein the shape of nanostructures is defined by a cross-sectional area as viewed from a direction normal to the surface and can be selected from a group consisting of: triangular, rectangular, hexagonal, octagonal, polygonal, circular, and elliptical shapes.

The diamond as defined in the above embodiment, wherein nanostructures within the plurality of nanostructures are categorized according to at least two different heights.

The diamond as defined in the above embodiment, wherein the nanostructures within the plurality of nanostructures are arranged in a periodic formation.

The diamond as defined in any one of the preceding embodiments, wherein at least two adjacent nanostructures are separated by a distance that ranges between 40 nanometers (nm) and 200 nm.

The diamond as defined in preceding embodiments, wherein the periodic formation is large enough to generate the structural colours that is visually discernable by human eyes.

The diamond in any one of the preceding embodiments, wherein each nanostructure is having a cross-sectional length that ranges between 100 nm and 500 nm, and is extended from the at least one surface of the diamond by a distance that is less than 500 nm.

The diamond as defined in any one of the preceding embodiments, wherein each nanostructure comprises a top surface, a bottom surface and a side surface, wherein the top surface is having a surface smoothness of less than 10 nm, the side surface is having a surface smoothness of less than 20 nm and the bottom surface is having smoothness of less than 10 nm.

The diamond as defined in any one of the preceding embodiments, wherein a group of nanostructures within the plurality of nanostructures is having one or more properties which are different than another group of nanostructures within the plurality of nanostructures.

The diamond as defined in any one of the preceding embodiments, further comprising: another plurality of nanostructures formed on the surface of the diamond, wherein another plurality of nanostructures generates other structural colours on the surface of the diamond, wherein the structural colours is different than the other structural colours.

The diamond as defined in any one of the preceding embodiments, further comprising another surface on the diamond that is on a different plane that the surface of the diamond, wherein the another surface comprises a plurality of nanostructures.

The diamond as defined in any one of the preceding embodiments is either mined, CVD or HPHT diamond.

The diamond as defined in any one of the preceding embodiments, the diamond is intrinsically a coloured diamond.

The diamond as defined in any one of the preceding embodiments, wherein the at least one surface is functionalized by a gaseous termination that is selected from group of gaseous terminations consisting of: hydrogen termination and oxygen termination.

In another embodiment, another diamond, comprising: at least one surface; and a plurality of nanostructures formed on the at least one surface of the diamond, wherein the plurality of nanostructures generates a visual perception on the at least one surface of the diamond.

The diamond as defined in the above embodiment, wherein the visual perception is selected from a group of perceptions consisting of: perception of colour, perception of depth and perception of size.

In an alternative embodiment, a method of forming a diamond that displays a structural colours, comprising: providing a surface of the diamond; and forming a plurality of nanostructures on the surface of the diamond, wherein the plurality of nanostructures generate a structural colours when shined with a visible light.

The method as defined in the above embodiment, wherein forming the plurality of nanostructure further comprises: etching the surface of the diamond to form the nanostructures.

The method as defined in the above embodiment, wherein the etching is using an inductive coupling plasma reactive ion etching (ICP/RIE).

The method as defined in the above embodiment, wherein gas composition when performing the ICP/RIE consists of gases selected from a group of: inert gas and chlorine, and wherein the inert gas is argon, helium, neon, krypton, xenon, or a mixture of more than one of these.

The method as defined in the above embodiment, wherein forming the plurality of nanostructure further comprises: coating a layer of resist onto the surface of the diamond; using a lithography technique, exposing selected area on the surface of the diamond; and developing nano-pattern on the surface of the diamond.

The method as defined in the above embodiment, wherein the lithography technique is selected from group consisting of: electron beam writing, proton beam writing, focused ion beam, laser interference lithography, self-assemble lithography, block copolymer lithography (BCP), and Anodic Aluminium Oxide (AAO) lithography.

The method as defined in the above embodiment, further comprising: functionalizing the surface with a gaseous termination that is selected from group of gaseous terminations consisting of: hydrogen termination and oxygen termination.

The method as defined in the above embodiment, further comprising: forming another plurality of nanostructures on the surface of the diamond, wherein the plurality of nanostructures generate another structural colours when shined with the visible light.

1. A diamond comprising of:
at least one surface; and
a plurality of nanostructures formed on the at least one surface of the diamond,
wherein the plurality of nanostructures generates one or more structural colors on the surface of the diamond.

2. (canceled)

3. The diamond according to claim 1, wherein nanostructures within the plurality of nanostructures are identical in shapes or are categorized to at least two different shapes.

4. (canceled)

5. The diamond according to claim 1, wherein the shape of nanostructures is defined by a cross-sectional area as viewed from a direction normal to the surface and can be selected from a group consisting of: triangular, rectangular, hexagonal, octagonal, polygonal, circular, and elliptical shapes.

6. The diamond according to claim 1, wherein nanostructures within the plurality of nanostructures are categorized according to at least two different heights.

7. The diamond according to claim 1, wherein the nanostructures within the plurality of nanostructures are arranged in a periodic formation.

8. The diamond according to claim 1, wherein at least two adjacent nanostructures are separated by a distance that ranges between 40 nanometers (nm) and 200 nm.

9. The diamond according to claim 7, wherein the periodic formation is large enough to generate the structural colors that is visually discernable by human eyes.

10. The diamond according to claim 1, wherein each nanostructure is having a cross-sectional length that ranges between 100 nm and 500 nm, and is extended from the at least one surface of the diamond by a distance that is less than 500 nm.

11. The diamond according to claim 1, wherein each nanostructure comprises a top surface, a bottom surface and a side surface, wherein the top surface is having a surface smoothness of less than 10 nm, the side surface is having a surface smoothness of less than 20 nm and the bottom surface is having smoothness of less than 10 nm.

12. The diamond according to claim 1, wherein a group of nanostructures within the plurality of nanostructures is having one or more properties which are different than another group of nanostructures within the plurality of nanostructures.

13. The diamond according to claim 1, further comprising: another plurality of nanostructures formed on the surface of the diamond, wherein another plurality of nanostructures generates other structural colors on the surface of the diamond, wherein the structural colors is different than the other structural colors.

14. The diamond according to claim 1, further comprising another surface on the diamond that is on a different plane that the surface of the diamond, wherein the another surface comprises a plurality of nanostructures.

15. The diamond according to claim 1, wherein the diamond is either mined, CVD or HPHT diamond.

16. The diamond according to claim 1, wherein the diamond is intrinsically a coloured colored diamond.

17. The diamond according to claim 1, wherein at least one surface is functionalized by a gaseous termination that is selected from group of gaseous terminations consisting of: hydrogen termination and oxygen termination.

18. (canceled)

19. (canceled)

20. A method of forming a diamond that displays a structural colors, comprising:
providing a surface of the diamond; and
forming a plurality of nanostructures on the surface of the diamond,
wherein the plurality of nanostructures generate a structural colors when shined with a visible light.

21. The method according to claim 20, wherein forming the plurality of nanostructure further comprises: etching the surface of the diamond to form the nanostructures.

22. The method according to claim 21, wherein the etching is using an inductive coupling plasma reactive ion etching (ICP/RIE).

23. The method according to claim 22, wherein gas composition when performing the ICP/RIE consists of gases selected from a group of: inert gas and chlorine, and wherein the inert gas is argon, helium, neon, krypton, xenon, or a mixture of more than one of these.

24. The method according to claim 23, wherein forming the plurality of nanostructure further comprises: coating a layer of resist onto the surface of the diamond; using a lithography technique, exposing selected area on the surface of the diamond; and developing nano-pattern on the surface of the diamond.

25. The method according to claim 24, wherein the lithography technique is selected from group consisting of: electron beam writing, proton beam writing, focused ion beam, laser interference lithography, self-assemble lithography, block copolymer lithography (BCP), and Anodic Aluminium Aluminum Oxide (AAO) lithography.

26. The method according to claim 25, further comprising: functionalizing the surface with a gaseous termination that is selected from group of gaseous terminations consisting of: hydrogen termination and oxygen termination.

27. The method according to claim 26, further comprising: forming another plurality of nanostructures on the surface of the diamond, wherein the plurality of nanostructures generate another structural colors when shined with the visible light.
